(19) United States
(12) Patent Application Publication
(10) Pub. No.: US 2021/0151468 A1
(43) Pub. Date: May 20, 2021

(54) ARRAY SUBSTRATE, DISPLAY PANEL AND DISPLAY DEVICE

(71) Applicants: Beijing BOE Display Technology Co., Ltd., Beijing (CN); BOE Technology Group Co., Ltd., Beijing (CN)

(72) Inventors: Xiaoying LI, Beijing (CN); Yan Yan, Beijing (CN); Xue Wang, Beijing (CN); Tingting Wang, Beijing (CN); Yaya Qi, Beijing (CN); Xiao Wang, Beijing (CN); Zhiqiang Ma, Beijing (CN)

(73) Assignees: Beijing BOE Display Technology Co., Ltd.; BOE Technology Group Co., Ltd.

(21) Appl. No.: 16/826,624

(22) Filed: Mar. 23, 2020

(30) Foreign Application Priority Data
Nov. 19, 2019 (CN) 201911135058.6

(51) Int. Cl. H01L 27/12; H01L 23/538

(52) U.S. Cl. CPC H01L 27/124; H01L 23/5386

(57) ABSTRACT

The present disclosure discloses an array substrate, a display panel and a display device. The array substrate comprises: a substrate, multiple signal lines arranged on a side of the substrate and extending along a first direction, and multiple lead terminals connected with the multiple signal lines respectively; wherein the multiple lead terminals each comprises: a bonding area configured to be bonded with a flexible printed circuit board, and a bending area located at a side of the bonding area facing away from a connected signal line, wherein the lead terminal is bent-shaped in the bending area.

### CROSS-REFERENCE TO RELATED APPLICATION

This application claims priority of Chinese Patent Application No. 201911135058.6, filed with the Chinese Patent Office on Nov. 19, 2019, which is hereby incorporated by reference in its entirety.

### FIELD

The present disclosure relates to the technical field of display, in particular to an array substrate, a display panel and a display device.

### BACKGROUND

Flat Panel Displays (FPDs) have become mainstream products in the market, and more and more types of flat panel displays are available, such as Liquid Crystal Displays (LCDs), Organic Light Emitted Diode (OLED) displays, Plasma Display Panels (PDPs), Field Emission Displays (FEDs), and the like.

### SUMMARY

The embodiment of the present disclosure provides an array substrate, including:

a substrate;

multiple signal lines arranged on a side of the substrate and extending along a first direction; and

multiple lead terminals connected with the multiple signal lines respectively;

wherein the multiple lead terminals each includes:
a bonding area configured to be bonded with a flexible printed circuit board, and
a bending area located at a side of the bonding area facing away from a connected signal line, wherein the lead terminal is bent-shaped in the bending area.

In one possible implementation, the lead terminal, in the bending area, is composed of:

multiple S-shaped structures connected in turn, or

multiple broken line-shaped structures connected in turn, or

multiple bow-shaped structures connected in turn.

In one possible implementation, when the lead terminal, in the bending area, is composed of multiple bow-shaped structures connected in turn;

the multiple bow-shaped structures each includes:

an extending part extending along a second direction; and

a connecting part extending along a direction vertical to the second direction;

wherein length of the connecting part in the direction vertical to the second direction is smaller than length of the extending part in the second direction, and the second direction is a extending direction of the lead terminal.

In one possible implementation, width of the connecting part in the second direction is greater than width of the extending part in the direction vertical to the second direction.

In one possible implementation, the lead terminal is strip-shaped in the bonding area.

In one possible implementation, the width of the lead terminal, in the bonding area, in the direction vertical to the second direction is same as the length of the connecting part in the direction vertical to the second direction.

In one possible implementation, the lead terminal further comprises an extending area at a side of the bending area facing away from the bonding area, and the lead terminal is strip-shaped in the extending area.

In one possible implementation, different lead terminals have the same shape with each other in the bending area.

The embodiment of the present disclosure further provides a display panel which includes the array substrate provided in the embodiment of the present disclosure.

The embodiment of the present disclosure further provides a display device which includes the display panel provided in the embodiment of the present disclosure.

### BRIEF DESCRIPTION OF THE DRAWINGS

FIG. 1 is a structural schematic diagram of a top view of an array substrate provided in an embodiment of the present disclosure;

FIG. 2 is a structural schematic diagram of a sectional view of an array substrate provided in an embodiment of the present disclosure;

FIG. 3 is a structural schematic diagram of a local structure of an array substrate provided in an embodiment of the present disclosure.

FIG. 4 is a structural schematic diagram of sectional view of an array substrate provided in another embodiment of the present disclosure.

FIG. 5 is a structural schematic diagram of a top view of multiple S-shaped lead terminals of the bending area provided in an embodiment of the present disclosure;

FIG. 6 is a structural schematic diagram of a top view of multiple broken line-shaped lead terminals of the bending area provided in an embodiment of the present disclosure;

FIG. 7 is a structural schematic diagram of a top view of multiple bow-shaped lead terminals of the bending area provided in an embodiment of the present disclosure;

FIG. 8 is an enlarged structural schematic diagram of a bow-shaped lead terminal of the bending area provided in an embodiment of the present disclosure.

### DETAILED DESCRIPTION OF THE EMBODIMENTS

In order to make the objectives, technical solutions, and advantages of the present disclosure clearer, the technical solutions of the embodiments of the present disclosure will be described clearly and completely below in combination with accompanying drawings of the embodiments of the present disclosure. Apparently, the described embodiments are only a part but not all of the embodiments of the present disclosure. Based upon the described embodiments of the present disclosure, all of the other embodiments obtained by those skilled in the art without any creative effort shall all fall within the protection scope of the present disclosure.

Unless otherwise defined, the technical or scientific terms used in the present disclosure shall have a general meaning understood by those skilled in the art to which the present disclosure belongs. The terms “first”, “second” and the like used in the present disclosure do not indicate any order, quantity, or importance, but are merely intended to distinguish different components. Words like “include” or “including” mean that the element or object preceding the word covers the element or object listed after the word and its equivalent, without excluding other elements or objects. Words like “connection” or “connected” are not limited to physical or mechanical connections, but can include electrical connections, whether direct or indirect. Terms like “upper”, “lower”, “left”, and “right” are merely intended to represent the relative position relationship, and when the absolute position of the described object changes, the relative positional relationship may also change correspondingly.

In order to keep the following description of the embodiments of the present disclosure clear and concise, the detailed description of known functions and known components is omitted in the present disclosure.

Along with widespread applications of display panels, technologies and designs aiming at solving various problems of poor display and optimizing the display effect are also gradually developing. For the design of traditional micro-linear lead terminals, the adhesive forces between the lead terminals and the substrate are relatively low, easily causing a variety of phenomena of falling off. For example, the lead terminal may fall off at the polishing edge or the cutting edge, thereby further leading to falling off of the whole lead terminal, moreover, when COF Bonding Rework is required since error occurs to the bonding position of the lead terminal and the flexible printed circuit board, the lead terminal will also fall off due to an adhesive force, while the falling off of the lead terminal will lead to unsuccessful entrance of part of the signals into the display panel, thereby leading to poor display.

Therefore, the present disclosure provides an array substrate, a display panel and a display device, to improve the problem of poor display of the display panel due to easy falling off of the lead terminal in related techniques.

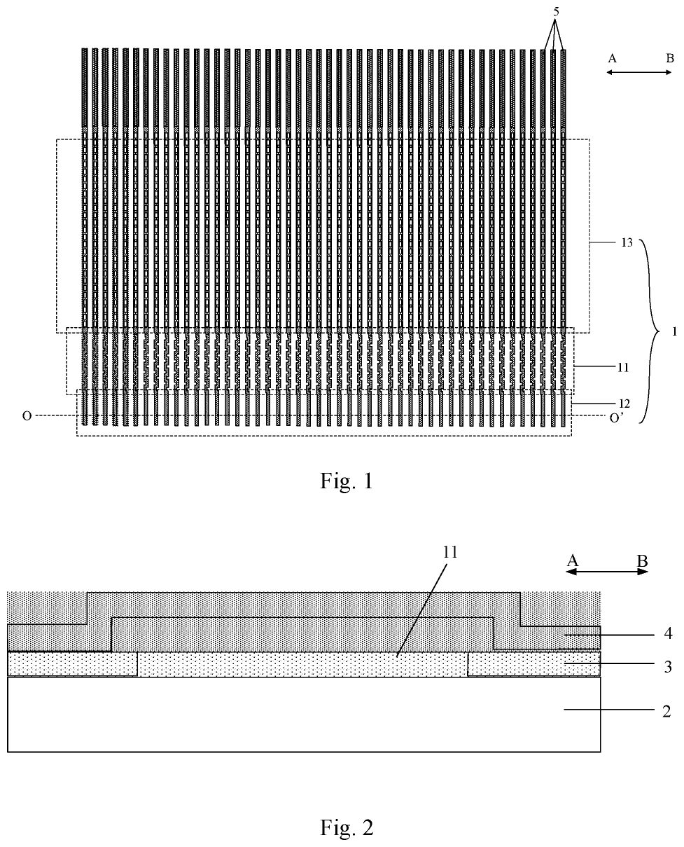

Please refer to FIGS. 1 to 4, the embodiment of the present disclosure provides an array substrate, including: a substrate 2, multiple signal lines 5 arranged on a side of the substrate 2 and extending along a first direction AB, and multiple lead terminals 1 connected with the multiple signal lines 5 respectively; wherein,

the multiple lead terminals 1 each includes: a bonding area 13 configured to be bonded with a flexible printed circuit board (not shown in the figure), and a bending area 11 located at a side of the bonding area 13 facing away from a connected signal line 5, wherein the lead terminal 1 is bent-shaped in the bending area 11.

The array substrate provided in the embodiment of the present disclosure includes a substrate 2, multiple signal lines 5 arranged on a side of the substrate 2 and extending along a first direction AB, and multiple lead terminals 1 connected with the multiple signal lines 5 respectively; wherein, the multiple lead terminals 1 each includes: a bonding area 13 configured to be bonded with a flexible printed circuit board, and a bending area 11 located at a side of the bonding area 13 facing away from a connected signal line 5, and the lead terminal 1 is bent-shaped in the bending area 11, that is, the part of the lead terminal 1 close to the bonding area 13 is manufactured to be bent-shaped. Compared with a linear lead terminal, on the one hand, the bent-shaped part of the lead terminal 1 can increase contact area between the lead terminal 1 and the substrate 2 and enhance adhesion, and on the other hand, the bent-shaped part of the lead terminal 1 can also produce variability in the forced direction, and enhance the adhesion between the lead terminal 1 and the substrate 2, thereby improving the following problems in related techniques: the lead terminals 1 easily fall off at the polishing edge or the cutting edge (such as the dotted line OO′ in FIG. 1), which further leads to falling off of the whole lead terminal, moreover, the lead terminals 1 easily falls off due to an adhesive force when bonding rework is required between the lead terminals and a flexible printed circuit board, which leads to poor display of the display panel.

It should be noted that, FIG. 1 intends to clearly show the lead terminals on the array substrate. Only the local structural schematic diagram of the array substrate is shown, and the present disclosure is not limited hereto. The length of a signal line 5 can be greater than the length of a lead terminal 1, and the quantity of the lead terminals 1 can also be greater than the quantity shown in FIG. 1.

Optionally, FIG. 2 which is a structural schematic diagram of a sectional view of an array substrate provided in an embodiment of the present disclosure illustrates that the array substrate is further provided with a gate insulating layer 3 on the side of the lead terminal 1 facing away from the substrate 2, and a passivation layer 4 is further arranged on the side of the gate insulating layer 3 facing away from the lead terminal 1. The substrate 2 can be a glass substrate, and the thickness can range from 490 μm to 510 μm, specifically, the thickness can be 500 μm. The material of the gate insulating layer 3 can be SiNx, and the thickness of the gate insulating layer 3 can range from 0.3 μm to 0.5 μm, specifically, the thickness can be 0.4 μm. The material of the passivation layer 4 can be SiNx, and the thickness of the passivation layer 4 can range from 0.3 μm to 0.5 μm, specifically, the thickness can be 0.4 μm. The material of a lead terminal 1 can include an NbMo metal layer and a copper metal layer which can be arranged in a laminated manner, wherein the NbMo metal layer can be arranged between the copper metal layer and the substrate, and the thickness of the NbMo metal layer can range from 0.02 μm to 0.04 μm, specifically, the thickness can be 0.03 μm. The thickness of the copper metal layer can range from 0.3 μm to 0.5 μm, specifically, the thickness can be 0.5 μm. In addition, the material of a lead terminal 1 can also include a molybdenum metal layer, an aluminum metal layer and a molybdenum metal layer which are arranged in turn in a laminated manner, wherein the thickness of the molybdenum metal layer can range from 0.1 μm to 0.2 μm, specifically, the thickness can be 0.15 μm. The thickness of the aluminum metal layer can range from 0.3 μm to 0.5 μm, specifically, the thickness can be 0.35 μm.

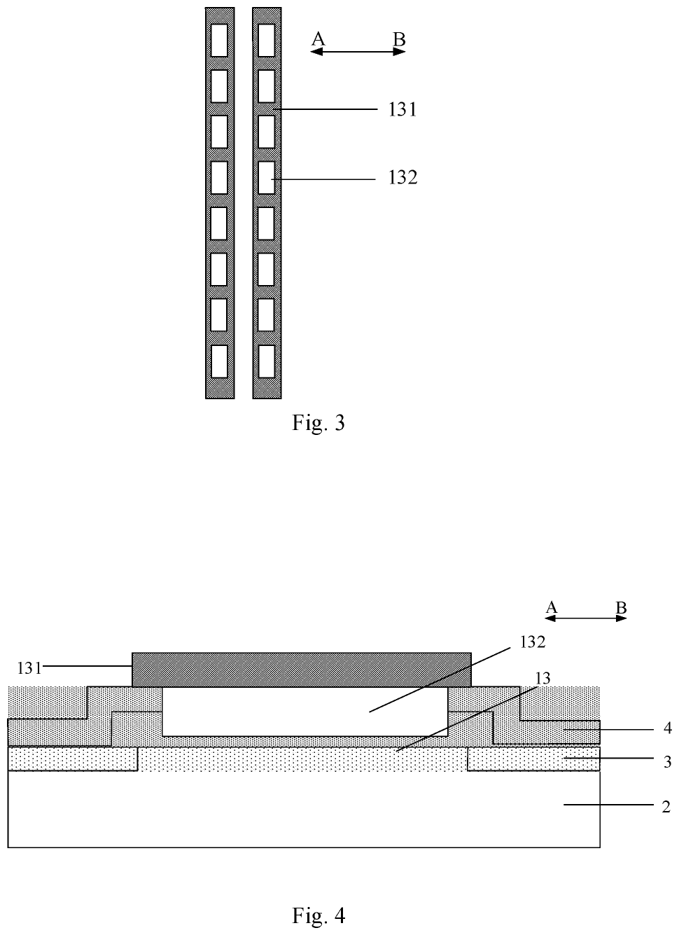

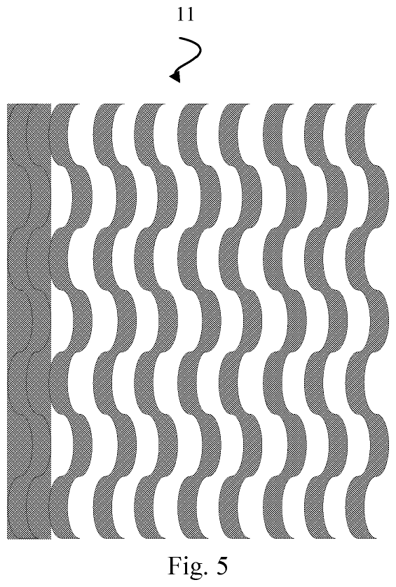

Optionally, a local structure of the bonding area 13 is shown in FIG. 3, which includes an Indium Tin Oxide (ITO) layer 131 and via holes 132. In some embodiments, the sectional view of the array substrate in the bonding area 13 along the first direction AB is shown in FIG. 4. In the FIG. 4, the ITO layer 131 covers the passivation layer 4, and is electrically connected to the lead terminal 1 through via holes 132 penetrating the passivation layer 4 and the gate insulating layer 3. Optionally, the projection width of the ITO layer 131 on the substrate 2 in the first direction AB is not less than that of a lead terminal 1 on the substrate 2 in the first direction AB. Optionally, the thickness of the ITO layer 131 can range from 0.01 um to 0.1 um, specifically, the thickness can be 0.04 um.

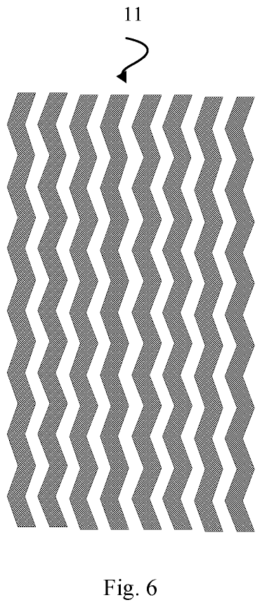

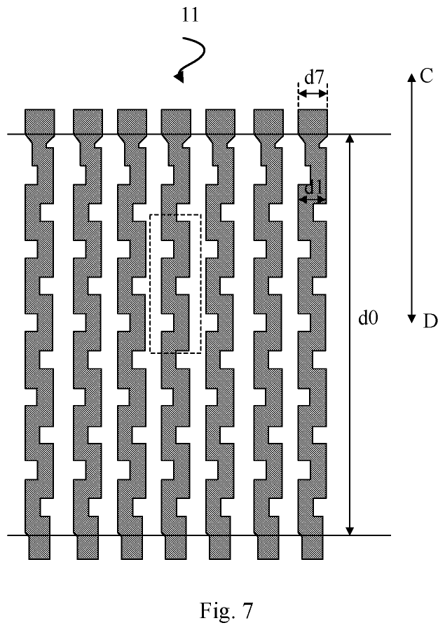

During some implementations, the lead terminal 1 can have many bending shapes, for example, as shown in FIG. 5, the lead terminal 1, in the bending area 11, is composed of multiple S-shaped structures which are connected in turn; for another example, as shown in FIG. 6, the lead terminal 1, in the bending area 11, is composed of multiple broken line-shaped structures which are connected in turn; and still for another example, as shown in FIG. 7, the lead terminal 1, in the bending area 11, is composed of multiple bow-shaped structures which are connected in turn.

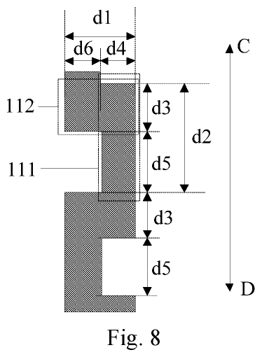

During some implementations, in combination with FIG. 7 and FIG. 8, the lead terminal 1, in the bending area 11, is composed of multiple bow-shaped structures (as shown by the dashed box in FIG. 7) which are connected in turn; the bow-shaped structure includes an extending part 111 extending along a second direction CD and a connecting part 112 extending along a direction vertical to the second direction CD; and the length d1 of the connecting part 112 in the direction vertical to the second direction CD is smaller than the length d2 of the extending part 111 in the second direction CD, wherein the second direction CD is a extending direction of the lead terminal 1. In the embodiment of the present disclosure, the lead terminal 1, in the bending area 11, is composed of multiple bow-shaped structures which are connected in turn, compared with other bent-shaped structures (such as an S-shaped structure and a broken line-shaped structure), the bow-shaped lead terminal 1 is more beneficial for manufacturing of practical process. In addition, compared with the condition in which the length d1 of the connecting part 112 in the direction vertical to the second direction CD is larger, the length d1 of the connecting part 112 in the direction vertical to the second direction CD is smaller than the length d2 of the extending part 111 in the second direction CD, therefore, the lead terminal 1 has better adhesion.

During some implementations, since lead terminals 1 at different positions of the array substrate may be inclined in different angles, that is, for example, multiple lead terminals 1 of the array substrate are arranged in one row, a larger angle of inclination (such as 20 degrees) is possibly formed between the lead terminal at the edge in a row and the vertical direction, and further the second direction is the direction which has a corresponding angle of inclination (such as 20 degrees) with the vertical direction. The lead terminals 1 in the middle position in a row may have a smaller angle of inclination, for example, the lead terminals 1 may be arranged vertically, and therefore, the second direction is a direction coincident with the vertical direction. Of course, if multiple lead terminals 1 are all arranged vertically, that is, they are in the same extending direction as the extending direction of the signal lines 5, then the second direction CD is the direction overlapped with the first direction AB.

During some implementations, as shown in FIG. 8, the width d3 of the connecting part 112 in the second direction CD is greater than the width d4 of the extending part 111 in the direction vertical to the second direction CD. In the embodiment of the present disclosure, if the lead terminal 1 produces a tearing force along its extending direction, the width d3 of the connecting part 112 in the second direction CD is greater than the width d4 of the extending part 111 in the direction vertical to the second direction CD, such that the lead terminal 1 has a greater adhesion in the direction vertical to the extending direction of the lead terminal 1, thereby reducing possibility of being torn off of the lead terminal.

During some implementations, in combination with FIG. 7 and FIG. 8, the length d0 of the lead terminal 1 along the second direction CD in the bending area 11 can range from 300 μm to 360 μm, specifically, the length d0 can be 330 μm. The width d3 of the connecting part 112 in the second direction CD can range from 13.0 μm to 13.6 μm, specifically, the width d3 can be 13.4 μm. The width d4 of the extending part 111 in a direction vertical to the second direction CD can range from 9.95 μm to 10.05 μm, specifically, the width d4 can be 10.0 μm. The length d6 of the gap between two adjacent connecting parts 112 in a direction vertical to the second direction CD can range from 9.85 μm to 9.95 μm, specifically, the length d6 can be 9.9 μm. The length d5 of the gap between two adjacent connecting parts 112 in the second direction CD can range from 16.0 μm to 17.0 μm, specifically, the length d5 can be 16.6 μm.

During some implementations, in combination with FIG. 1, the lead terminal 1, in the bonding area 13, is strip-shaped, that is, for example, the lead terminal 1 can be of a rectangular shape in the bonding area 13. That is, in the embodiment of the present disclosure, the lead terminal 1, in the bonding area 13, is strip-shaped, thereby being beneficial for pressing connection between the lead terminal 1 and the flexible printed circuit board.

During some implementations, in combination with FIG. 7, the width d7 of the lead terminal 1 along a direction vertical to the second direction CD in the bonding area 13 is the same as the width d1 of the connecting part 112 along a direction vertical to the second direction CD. In the embodiment of the present disclosure, the width d7 of the lead terminal 1 along a direction vertical to a second direction CD in the bonding area 13 is the same as the length d1 of the connecting part 112 in a direction vertical to the second direction CD, thereby being beneficial for composition of the lead terminal 1.

During some implementations, in combination with FIG. 1, the lead terminal 1 is further provided with an extending area 12 at the side of the bending area 11 facing away from the bonding area 13, and the lead terminal 1 of the extending area 12 is strip-shaped. In the embodiment of the present disclosure, the lead terminal 1 of the extending area 12 is strip-shaped.

During some implementations, in combination with FIG. 1, different lead terminals 1 have the same shape with each other in the bending area 11. In the embodiment of the present disclosure, different lead terminals 1 have the same shape with each other in the bending area 11, thereby lowering difficulty of the whole manufacturing process of the lead terminal 1 of the array substrate.

An embodiment of the present disclosure further provides a display panel which includes the array substrate provided in the embodiment of the present disclosure.

An embodiment of the present disclosure further provides a display device which includes the display panel provided in the embodiment of the present disclosure.

The embodiment of the present disclosure has the following beneficial effects: the array substrate provided in the embodiment of the present disclosure includes a substrate, multiple signal lines arranged on a side of the substrate and extending along a first direction, and multiple lead terminals connected with the multiple signal lines respectively, wherein the multiple lead terminals each includes: a bonding area configured to be bonded with a flexible printed circuit board, and a bending area located at a side of the bonding area facing away from a connected signal line, and the lead terminal is bent-shaped in the bending area, that is, the part of the lead terminal close to the bonding area is manufactured to be bent-shaped. Compared with a linear lead terminal, on the one hand, the bent-shaped part of the lead terminal can increase contact area between the lead terminal and the substrate and enhance adhesion, and on the other hand, the bent-shaped part of the lead terminal can also produce variability in the forced direction, and enhance the adhesion between the lead terminal and the substrate, thereby improving the problem of poor display of the display panel due to easy falling off of the lead terminal in related techniques.

Evidently, those skilled in the art can make various modifications and variations to the present disclosure without departing from the spirit and scope of the present disclosure. Accordingly, the present disclosure is also intended to encompass these modifications and variations thereto so long as the modifications and variations come into the scope of the claims appended to the present disclosure and their equivalents.

1. An array substrate comprising:
a substrate;
multiple signal lines arranged on a side of the substrate and extending along a first direction; and
multiple lead terminals connected with the multiple signal lines respectively;
wherein the multiple lead terminals each comprises:
a bonding area configured to be bonded with a flexible printed circuit board; and
a bending area located at a side of the bonding area facing away from a connected signal line, wherein the lead terminal is bent-shaped in the bending area.

2. The array substrate of claim 1, wherein the lead terminal, in the bending area, is composed of:
multiple S-shaped structures connected in turn, or
multiple broken line-shaped structures connected in turn, or
multiple bow-shaped structures connected in turn.

3. The array substrate of claim 2, wherein when the lead terminal, in the bending area, is composed of multiple bow-shaped structures connected in turn, the multiple bow-shaped structures each comprises:
an extending part extending along a second direction; and
a connecting part extending along a direction vertical to the second direction;
wherein length of the connecting part in the direction vertical to the second direction is smaller than length of the extending part in the second direction, and the second direction is a extending direction of the lead terminal.

4. The array substrate of claim 3, wherein width of the connecting part in the second direction is greater than width of the extending part in the direction vertical to the second direction.

5. The array substrate of claim 3, wherein the lead terminal is strip-shaped in the bonding area.

6. The array substrate of claim 5, wherein width of the lead terminal, in the bonding area, in the direction vertical to the second direction is same as the length of the connecting part in the direction vertical to the second direction.

7. The array substrate of claim 5, wherein the lead terminal further comprises an extending area at a side of the bending area facing away from the bonding area, and the lead terminal is strip-shaped in the extending area.

8. The array substrate of claim 1, wherein different lead terminals have the same shape with each other in the bending area.

9. A display panel, comprising an array substrate, wherein the array substrate comprises:
a substrate;
multiple signal lines arranged on a side of the substrate and extending along a first direction; and
multiple lead terminals connected with the multiple signal lines respectively; and
wherein the multiple lead terminals each comprises:
a bonding area configured to be bonded with a flexible printed circuit board; and
a bending area located at a side of the bonding area facing away from a connected signal line, wherein the lead terminal is bent-shaped in the bending area.

10. The display panel of claim 9, wherein the lead terminal, in the bending area, is composed of:
multiple S-shaped structures connected in turn, or
multiple broken line-shaped structures connected in turn, or
multiple bow-shaped structures connected in turn.

11. The display panel of claim 10, wherein when the lead terminal, in the bending area, is composed of multiple bow-shaped structures connected in turn, the multiple bow-shaped structures each comprises:
an extending part extending along a second direction; and
a connecting part extending along a direction vertical to the second direction;
wherein length of the connecting part in the direction vertical to the second direction is smaller than length of the extending part in the second direction, and the second direction is a extending direction of the lead terminal.

12. The display panel of claim 11, wherein width of the connecting part in the second direction is greater than width of the extending part in the direction vertical to the second direction.

13. The display panel of claim 11, wherein the lead terminal is strip-shaped in the bonding area.

14. The display panel of claim 13, wherein width of the lead terminals, in the bonding area, in the direction vertical to the second direction is same as the length of the connecting part in the direction vertical to the second direction

15. The display panel of claim 13, wherein the lead terminals further comprises an extending area at a side of the bending area facing away from the bonding area, and the lead terminal is strip-shaped in the extending area.

16. The display panel of claim 9, wherein different lead terminals have the same shape with each other in the bending area.

17. A display device, comprising the display panel of claim 9.

18. The display device of claim 17, wherein the lead terminal, in the bending area, is composed of:
multiple S-shaped structures connected in turn, or
multiple broken line-shaped structures connected in turn, or
multiple bow-shaped structures connected in turn.

19. The display device of claim 18, wherein when the lead terminal, in the bending area, is composed of multiple bow-shaped structures connected in turn, the multiple bow-shaped structures each comprises:
an extending part extending along a second direction; and
a connecting part extending along a direction vertical to the second direction;
wherein length of the connecting part in the direction vertical to the second direction is smaller than length of the extending part in the second direction, and the second direction is a extending direction of the lead terminal.

20. The display device of claim 19, wherein width of the connecting part in the second direction is greater than width of the extending part in the direction vertical to the second direction.
